(19) United States
(12) Patent Application Publication
(10) Pub. No.: US 2025/0208200 A1
(43) Pub. Date: Jun. 26, 2025

(54) ABNORMALITY DETECTION DEVICE

(71) Applicant: Murata Manufacturing Co., Ltd., Nagaokakyo-shi (JP)

(72) Inventor: Tetsuya NARITA, Nagaokakyo-shi (JP)

(21) Appl. No.: 19/077,472

(22) Filed: Mar. 12, 2025

Related U.S. Application Data
(63) Continuation of application No. PCT/JP2023/036186, filed on Oct. 4, 2023.

(30) Foreign Application Priority Data
Oct. 14, 2022 (JP) 2022-165544

(51) Int. Cl. G01R 31/28; G01R 19/165

(52) U.S. Cl. CPC G01R 31/2884; G01R 19/1659

(57) ABSTRACT

A first detection circuit and a second detection circuit are provided that output first signals when detecting corresponding abnormal states. A first register and a second register store data corresponding to the first signals input from the corresponding detection circuits and output second signals. The first selection circuit and the second selection circuit determine whether to output third signals based on the second signals input from the corresponding registers among the first register and the second register. An OR circuit outputs a fourth signal based on the third signals input from the first selection circuit and the second selection circuit. One output terminal outputs the fourth signal, which is output from the OR circuit, as an abnormality detection signal.

### CROSS REFERENCE TO RELATED APPLICATIONS

This application is a continuation of International Application No. PCT/JP2023/036186, filed Oct. 4, 2023, which claims priority to Japanese Patent Application No. 2022-165544, filed Oct. 14, 2022, the contents of each of which are hereby incorporated by reference in their entirety.

### TECHNICAL FIELD

The present disclosure relates to an abnormality detection device.

### BACKGROUND

Currently, there are devices for detecting abnormal states of a semiconductor device provided in various types of electronic devices. For example, such a device is described in Japanese Unexamined Patent Application Publication No. 2002-055830 in which there is an interrupt signal generating device that includes a detection unit that detects various abnormal states, such as an abnormal state of a power supply, and an output terminal that outputs an interrupt signal when an abnormality is detected by the detection unit. The interrupt signal generating device is configured such that an interrupt signal is output from the output terminal to an internal bus of the semiconductor device.

For the semiconductor device, it is required to detect abnormal states inside of the semiconductor device and to output detection signals indicating the detection of the abnormal states to the outside of the semiconductor device. An existing abnormality detection device for such a semiconductor device includes multiple detection circuits that detect various abnormal states, multiple registers that are provided for the corresponding detection circuits and store data of detection signals output from the corresponding detection circuits, and multiple output terminals that are provided for the corresponding registers and output the detection signals read from the corresponding registers to the outside of the semiconductor device.

However, with the related-art abnormality detection device, which includes multiple output terminals corresponding to the number of the detection circuits for detecting abnormal states as described above, the number of the output terminals may become excessively large, and the area of a semiconductor substrate used to output abnormality detection signals may become excessively large.

### SUMMARY OF THE INVENTION

In view of the foregoing, it is an object of the present disclosure to provide an abnormality detection device that minimizes an increase in the area of a semiconductor substrate used to output abnormality detection signals.

In an exemplary aspect of the present disclosure, an abnormality detection device is provided for detecting multiple abnormal states that are likely to occur in a semiconductor device. In this aspect, the abnormality detection device includes a plurality of detection circuits, a plurality of registers, a plurality of selection circuits, an OR circuit, and one output terminal. The detection circuits are provided for the corresponding abnormal states and output first signals when detecting the corresponding abnormal states. The registers are provided for the corresponding detection circuits, store data corresponding to the first signals input from the corresponding detection circuits, and output second signals based on the stored data. The selection circuits are provided for the corresponding registers and determine whether to output third signals based on the second signals input from the corresponding registers. The OR circuit is configured to receive the third signals from the selection circuits and outputs a fourth signal based on the received third signals. The output terminal outputs the fourth signal output from the OR circuit as an abnormality detection signal indicating the detection of an abnormal state.

In another exemplary aspect, an abnormality detection device of the present disclosure is provided for detecting multiple abnormal states that are likely to occur in a semiconductor device and includes a plurality of detection circuits, a plurality of registers, a plurality of selection circuits, an OR circuit, a bypass circuit, an exclusive-OR circuit, and an output terminal. The detection circuits are provided for the corresponding abnormal states and output first signals when detecting the corresponding abnormal states. The registers are provided for the corresponding detection circuits, store data corresponding to the first signals input from the corresponding detection circuits, and output second signals based on the stored data. The selection circuits are provided for the corresponding registers and determine whether to output third signals based on the second signals input from the corresponding registers. The OR circuit is configured to receive the third signals from the selection circuits and to output a fourth signal based on the received third signals. The bypass circuit outputs a fifth signal corresponding to one of the first signals output from a detection circuit selected from the detection circuits, by bypassing the corresponding one of the registers and the corresponding one of the selection circuits. The exclusive-OR circuit is configured to receive the fourth signal output from the OR circuit and the fifth signal output from the bypass circuit and to output a sixth signal based on the received fourth and fifth signals. The output terminal outputs the sixth signal output from the exclusive-OR circuit as an abnormality detection signal indicating the detection of an abnormal state. The bypass circuit includes multiple selection switches that are provided for the corresponding detection circuits and are configured to select the corresponding detection circuits, and a pulse generation circuit configured to output the fifth signal implemented by a single-shot pulse signal based on the one of the first signals output from the detection circuit selected by one of the selection switches.

In the abnormality detection device according to an exemplary aspect of the present disclosure, the selection circuits are configured to determine whether to output the third signals based on the second signals input from the corresponding registers. This configuration reduces the number of third signals input to the OR circuit. The OR circuit outputs the fourth signal based on the received third signals from one output terminal as an abnormality detection signal. This configuration reduces the number of output terminals for outputting abnormality detection signals. In turn, reducing the number of output terminals used to output abnormality detection signals reduces the area of a semiconductor substrate used to output the abnormality detection signals.

In the abnormality detection device according to another exemplary aspect of the present disclosure, the selection circuits are configured to determine whether to output the third signals based on the second signals input from the corresponding registers. This configuration reduces the number of third signals input to the OR circuit. The OR circuit outputs the fourth signal based on the received third signals, and the exclusive-OR circuit outputs the sixth signal from one output terminal, as an abnormality detection signal, based on the fourth signal output from the OR circuit and the fifth signal output from the bypass circuit. This configuration reduces the number of output terminals used to output abnormality detection signals. In turn, reducing the number of output terminals used to output abnormality detection signals reduces the area of a semiconductor substrate used to output the abnormality detection signals.

### BRIEF DESCRIPTION OF DRAWINGS

FIG. 1 is a circuit diagram of an abnormality detection device according to a first exemplary embodiment.

FIG. 2 is a circuit diagram of an abnormality detection device according to a second exemplary embodiment.

FIG. 3 is a circuit diagram of a pulse generation circuit.

FIG. 4 is a timing chart showing signal levels at respective parts of the pulse generation circuit.

FIG. 5 is a truth table showing the relationship between inputs and outputs of an exclusive-OR circuit.

FIG. 6 is a timing chart showing a first example of abnormal state determination based on an output signal of the exclusive-OR circuit.

FIG. 7 is a timing chart showing a second example of abnormal state determination based on an output signal of the exclusive-OR circuit.

FIG. 8 is a diagram illustrating an example of a circuit area and a pad area for output terminals in the first through third exemplary embodiments.

### DETAILED DESCRIPTION OF EMBODIMENTS

Exemplary embodiments of the present disclosure are described below with reference to the drawings. Although multiple embodiments are described below, any appropriate combination of configurations described in the embodiments is envisaged at the time of application. The same reference number is assigned to the same or similar components in the drawings, and the descriptions of those components are not repeated.

### First Exemplary Embodiment

### (Configuration of Abnormality Detection Device 10)

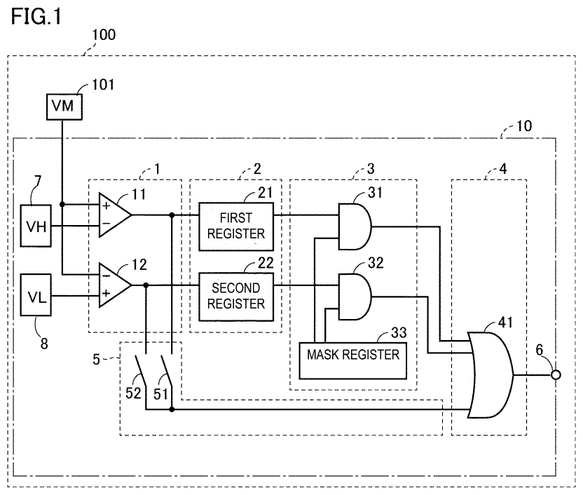

FIG. 1 is a circuit diagram of an abnormality detection device 10 according to a first exemplary embodiment.

As illustrated in FIG. 1, the abnormality detection device 10 is included in a semiconductor device 100. The abnormality detection device 10 includes an abnormality detection circuit 1, an abnormality storage register 2, an abnormality selection circuit 3, a logic circuit 4, a bypass circuit 5, and an output terminal 6. The abnormality detection device 10 further includes a first threshold storage circuit 7 and a second threshold storage circuit 8.

The semiconductor device 100 implements a current sensor that detects a predetermined current and outputs a signal indicating a detected current value. The semiconductor device 100 may also implement any other type of electronic device.

The abnormality detection circuit 1 detects multiple abnormal states in the semiconductor device 100 and outputs detection signals. The abnormality storage register 2 stores abnormal states detected by the abnormality detection circuit 1, stores detection signals output from the abnormality detection circuit 1, and outputs corresponding signals to the abnormality selection circuit 3. The abnormality selection circuit 3 outputs, to the logic circuit 4, selected signals among the signals output from the abnormality storage register 2. The logic circuit 4 performs a logical operation based on signals output from the abnormality selection circuit 3 and outputs a signal indicating the operation result to the output terminal 6.

The output terminal 6 outputs a signal output from the logic circuit 4 as an abnormality detection signal obtained by the abnormality detection device 10. The signal output from the output terminal 6 passes through a signal path provided in the semiconductor device 100 and is output to the outside of the semiconductor device 100 via an external output terminal of the semiconductor device 100.

Also, the output terminal 6 itself may have a function as an external output terminal that outputs signals to the outside of the semiconductor device 100. In this case, the signal output via the output terminal 6 of the abnormality detection device 10 is output to the outside of the semiconductor device 100 as an abnormality detection signal indicating the detection of an abnormal state in the semiconductor device 100.

In the exemplary aspect, a system that uses various signals output from the semiconductor device 100 is present outside of the semiconductor device 100. For example, when the semiconductor device 100 is a current sensor, an electric current detection signal is output from the semiconductor device 100 to a system that uses the current value detected by the semiconductor device 100. Also, an abnormality detection signal indicating the detection of an abnormal state in the semiconductor device 100 is output to the system that uses the current value detected by the semiconductor device 100.

The abnormality detection circuit 1 includes a first detection circuit 11 and a second detection circuit 12 that correspond to multiple abnormal states. The abnormality storage register 2 includes a first register 21 and a second register 22. The abnormality selection circuit 3 includes a first selection circuit 31 and a second selection circuit 32. The logic circuit 4 includes an OR circuit 41. The bypass circuit 5 includes a first selection switch 51 and a second selection switch 52.

In the abnormality storage register 2, the first register 21 corresponds to the first detection circuit 11. In the abnormality storage register 2, the second register 22 corresponds to the second detection circuit 12.

In the abnormality selection circuit 3, the first selection circuit 31 corresponds to the first register 21. In the abnormality selection circuit 3, the second selection circuit 32 corresponds to the second register 22. The first selection circuit 31 is an AND circuit including two input terminals, i.e., a first input terminal and a second input terminal, and one output terminal, and outputs, from the output terminal, an output signal with a level corresponding to the logical product of input signals from the first input terminal and the second input terminal. The second selection circuit 32 is an AND circuit that is similar to the first selection circuit 31.

The semiconductor device 100 includes a voltage monitor circuit 101. The voltage monitor circuit 101 converts a current value detected in the semiconductor device 100, which implements, for example, a current sensor, into a voltage value and outputs the voltage value as a monitor voltage VM.

The first threshold storage circuit 7 stores, as a first threshold value, an upper limit voltage VH indicating the upper limit of the monitor voltage. The first threshold storage circuit 7 outputs the stored upper limit voltage VH. The second threshold storage circuit 8 stores, as a second threshold value, a lower limit voltage VL indicating the lower limit of the monitor voltage. The second threshold storage circuit 8 outputs the stored lower limit voltage VL.

The first detection circuit 11 and the second detection circuit 12 are comparators. The first detection circuit 11 receives the monitor voltage VM and the upper limit voltage VH. The first detection circuit 11 outputs a high-level signal in an abnormal state in which the monitor voltage VM is higher than the upper limit voltage VH. The second detection circuit 12 receives the monitor voltage VM and the lower limit voltage VL. The second detection circuit 12 outputs a high-level signal in an abnormal state in which the monitor voltage VM is lower than the lower limit voltage VL. Thus, the first detection circuit 11 and the second detection circuit 12 correspond to multiple types of abnormal states.

The first detection circuit 11 outputs a signal toward the first register 21 and the first selection switch 51. When a high-level signal is output from the first detection circuit 11, the first register 21 stores the state of the high-level signal.

The second detection circuit 12 outputs a signal toward the second register 22 and the second selection switch 52. When a high-level signal is output from the second detection circuit 12, the second register 22 stores the state of the high-level signal.

An output signal from the first register 21 is input to the first selection circuit 31 from the first input terminal of the first selection circuit 31. An output signal from the second register 22 is input to the second selection circuit 32 from the first input terminal of the second selection circuit 32. Each of the first selection circuit 31 and the second selection circuit 32 is implemented by an AND circuit.

In an exemplary aspect, the mask register 33 is configured to select at least one of the first selection circuit 31 and the second selection circuit 32 to output a signal corresponding to the signal input from the corresponding register.

Specifically, the mask register 33 can select a circuit among the multiple circuits including the first selection circuit 31 and the second selection circuit 32 to output a signal by continuously applying a high-level signal to the second input terminal of the circuit.

Moreover, the mask register 33 can deselect a circuit among the multiple circuits including the first selection circuit 31 and the second selection circuit 32 to prevent the circuit from outputting a signal by continuously applying a low-level signal to the second input terminal of the circuit.

In the abnormality selection circuit 3, with the above-described function of the mask register 33, a high-level signal is applied to the second input terminal of a circuit among the multiple circuits including the first selection circuit 31 and the second selection circuit 32 to select the circuit to output a signal corresponding to an input signal from the corresponding register.

The signals output from the first selection circuit 31 and the second selection circuit 32 are input to the OR circuit 41.

When the first selection circuit 31 is selected to output a signal, and the first detection circuit 11 detects an abnormal state and outputs a high-level signal, a high-level signal is input to the OR circuit 41 via the first register 21 and the first selection circuit 31.

When the second selection circuit 32 is selected to output a signal, and the second detection circuit 12 detects an abnormal state and outputs a high-level signal, a high-level signal is input to the logical OR circuit 41 via the second register 22 and the second selection circuit 32.

In the exemplary aspect, the abnormality selection circuit 3 is configured such that a user of the abnormality detection device 10 can select at least one selection circuit that outputs a signal corresponding to an abnormal state detection signal by adjusting signals output from the mask register 33 to the first selection circuit 31 and the second selection circuit 32 as necessary. That is, the user can configured the mask register 33 to adjust its outputs as either a high signal or low signal fed to the selections circuits 31 and/or 32, such that the abnormality selection circuit 3 can cause both of the first selection circuit 31 and the second selection circuit 32 to output signals corresponding to abnormal state detection signals and cause one of the first selection circuit 31 and the second selection circuit 32 to output a signal corresponding to an abnormal state detection signal. This configuration enables the user to control the abnormality selection circuit 3 to output one or more signals corresponding to the types of abnormal state detection signals that are necessary for the user of the abnormality detection device 10. Thus, the abnormality selection circuit 3 can reduce the number of signals input to the OR circuit.

When the first selection switch 51 of the bypass circuit 5 is turned on, the output signal from the first detection circuit 11 passes through a signal path in the bypass circuit 5, bypasses the first register 21 and the first selection circuit 31, and is input to the OR circuit 41. For example, when the first selection switch 51 is turned on, and the first detection circuit 11 detects an abnormal state and outputs a high-level signal, a high-level signal is input to the OR circuit 41 via the first selection switch 51 and the signal path in the bypass circuit 5.

When the second selection switch 52 of the bypass circuit 5 is turned on, the output signal from the second detection circuit 12 passes through the signal path in the bypass circuit 5, bypasses the second register 22 and the second selection circuit 32, and is input to the OR circuit 41. For example, when the second selection switch 52 is turned on, and the second detection circuit 12 detects an abnormal state and outputs a high-level signal, a high-level signal is input to the OR circuit 41 via the second selection switch 52 and the signal path in the bypass circuit 5.

The OR circuit 41 outputs a signal indicating the logical sum of a signal input from the first selection circuit 31, a signal input from the second selection circuit 32, and a signal input from the bypass circuit 5. The signal output from the OR circuit 41 is output via the output terminal 6. When a high-level signal is output from the OR circuit 41, an abnormality detection signal indicating the detection of an abnormal state is output via the output terminal 6.

The output signals of the first detection circuit 11 and the second detection circuit 12 passing through the bypass circuit 5 bypass the abnormality storage register 2 and the abnormality selection circuit 3 and are therefore input to the OR circuit 41 more quickly compared with a case in which the output signals of the first detection circuit 11 and the second detection circuit 12 are input to the OR circuit 41 via the abnormality storage register 2 and the abnormality selection circuit 3, i.e., via a normal signal path.

For example, the user of the abnormality detection device 10 may turn on one of the first selection switch 51 and the second selection switch 52 that corresponds to a special abnormal state among multiple types of abnormal states that requires urgent attention when detected. Among multiple types of abnormal states, abnormal states other than special abnormal states may be referred to as standard abnormal states.

With the above configuration, when a detected abnormal state corresponds to one of the first selection switch 51 and the second selection switch 52 that is turned on, a detection signal is input to the OR circuit 41 via the bypass circuit 5. In this case, compared with a case in which the detection signal is input to the OR circuit 41 via the normal signal path, an abnormality detection signal is output via the output terminal 6 at an earlier timing.

As an example, the user of the abnormality detection device 10 may turn on the first selection switch 51 when an abnormal state, which is detected by the first detection circuit 11 when the monitor voltage VM output from the voltage monitor circuit 101 exceeds the upper limit voltage VH, needs to be addressed more urgently than an abnormal state detected by the second detection circuit 12 when the monitor voltage VM becomes lower than the lower limit voltage VL.

When the first selection switch 51 is turned on as described above, the first selection circuit 31 may be either enabled or disabled to output a signal. Similarly, when the second selection switch 52 is turned on, the second selection circuit 32 may be either enabled or disabled to output a signal.

For example, in a case in which the first selection switch 51 is turned off and the second selection circuit 32 is enabled to output a signal, when an abnormal state, in which the monitor voltage VM is lower than the lower limit voltage VL, is detected by the second detection circuit 12, an abnormality detection signal corresponding to the signal output from the second detection circuit 12 is output at a first timing from the output terminal 6 via the second register 22, the second selection circuit 32, and the OR circuit 41.

For example, in a case in which the first selection switch 51 is turned on and the first selection circuit 31 is enabled to output a signal, when an abnormal state, in which the monitor voltage VM is higher than the upper limit voltage VH, occurs, before an abnormality detection signal corresponding to the signal output from the first detection circuit 11 is output at a first timing from the output terminal 6 via the first register 21, the first selection circuit 31, and the OR circuit 41, an abnormality detection signal corresponding to the signal output from the first detection circuit 11 is output at a second timing earlier than the first timing from the output terminal 6 via the first selection switch 51 of the bypass circuit 5 and the OR circuit 41.

With the first embodiment described above, it is possible to achieve technical effects as described below. Regarding the detection signals output from the first detection circuit 11 and the second detection circuit 12, the multiple selection circuits including the first selection circuit 31 and the second selection circuit 32 make it possible to determine whether to output signals according to signals input from the corresponding first register 21 and second register 22 and thereby make it possible to reduce the number of signals input to the OR circuit 41. A signal output from the OR circuit 41 according to input signals is output as an abnormality detection signal from one output terminal 6. This configuration reduces the number of output terminals for outputting abnormality detection signals. In turn, reducing the number of output terminals 6 that output abnormality detection signals also reduces the area of a semiconductor substrate used to output abnormality detection signals.

Also, with the bypass circuit 5, signals output from detection circuits including the first detection circuit 11 and the second detection circuit 12, which are selected by multiple selection switches including the first selection switch 51 and the second selection switch 52, are input to the OR circuit 41 by bypassing the normal signal path consisting of the corresponding registers and selection circuits. This configuration enables an abnormality detection signal to be output via the output terminal 6 at an earlier timing compared with a case in which detection signals from the first detection circuit 11 and the second detection circuit 12 are input to the OR circuit 41 via the normal signal path.

The abnormality detection device 10 illustrated in FIG. 1 may also have a configuration not including the bypass circuit 5. Even with such a configuration, it is possible to reduce the area of a semiconductor substrate used to output abnormality detection signals.

### Second Exemplary Embodiment

### (Configuration of Abnormality Detection Device 10a)

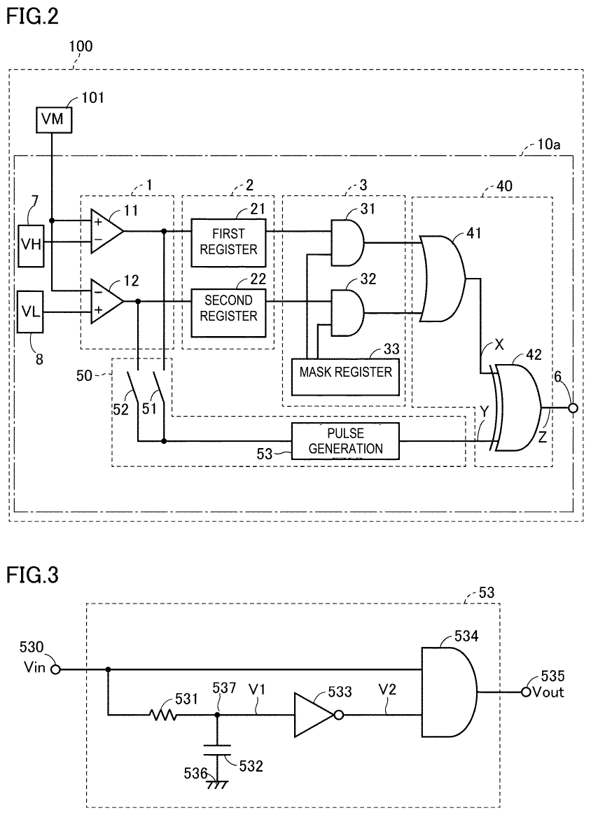

FIG. 2 is a circuit diagram of an abnormality detection device 10a according to a second exemplary embodiment. It is noted that differences in the configuration of the abnormality detection device 10a from the abnormality detection device 10 of the first exemplary embodiment are mainly described below.

The abnormality detection device 10a illustrated in FIG. 2 differs from the abnormality detection device 10 illustrated in FIG. 1 in the configurations of a logic circuit 40 and a bypass circuit 50. The logic circuit 40 includes an exclusive-OR circuit 42 in addition to the OR circuit 41. The bypass circuit 50 includes a pulse generation circuit 53 in addition to the first selection switch 51 and the second selection switch 52.

The OR circuit 41 receives a signal output from the first selection circuit 31 and a signal output from the second selection circuit 32. The OR circuit 41 outputs a signal indicating the logical sum of the signal input from the first selection circuit 31 and the signal input from the second selection circuit 32. The signal output from the OR circuit 41 is input to the exclusive-OR circuit 42.

In the bypass circuit 50, a signal output from the first selection switch 51 and a signal output from the second selection switch 52 are input to the pulse generation circuit 53. The pulse generation circuit 53 generates a single-shot pulse signal according to the signal input from the first selection switch 51 and the signal input from the second selection switch 52. The single-shot pulse signal output from the pulse generation circuit 53 is input to the exclusive-OR circuit 42.

The exclusive-OR circuit 42 outputs a signal indicating the exclusive OR of the signal input from the OR circuit 41 and the signal input from the pulse generation circuit 53. The signal output from the OR circuit 41 is output via the output terminal 6. The signal output from the exclusive-OR circuit 42 is an abnormality detection signal that indicates the detection of an abnormal state corresponding to a change in the signal as shown in FIGS. 5 to 7.

### (Configuration of Pulse Generation Circuit 53)

FIG. 3 is a circuit diagram of the pulse generation circuit 53. The pulse generation circuit 53 outputs a single-shot pulse signal in which an output voltage Vout of an output terminal 535 becomes high for a predetermined time period when an input voltage Vin of an input terminal 530 becomes high.

The pulse generation circuit 53 includes a resistor 531, a capacitor 532, an inverting circuit 533, and an AND circuit 534. A first input terminal of the AND circuit 534 is connected to the input terminal 530.

The resistor 531 and the capacitor 532 are connected in series between the input terminal 530 and a ground 536. The inverting circuit 533 is connected between a connection point 537 between the resistor 531 and the capacitor 532 and a second input terminal of the AND circuit 534.

The voltage at the connection point 537 of an RC circuit consisting of the resistor 531 and the capacitor 532 is input as an input voltage V1 to the inverting circuit 533. An output voltage V2 of the inverting circuit 533 is input to the second input terminal of the AND circuit 534. The output voltage Vout of the AND circuit 534 is input to an input terminal of the exclusive-OR circuit 42.

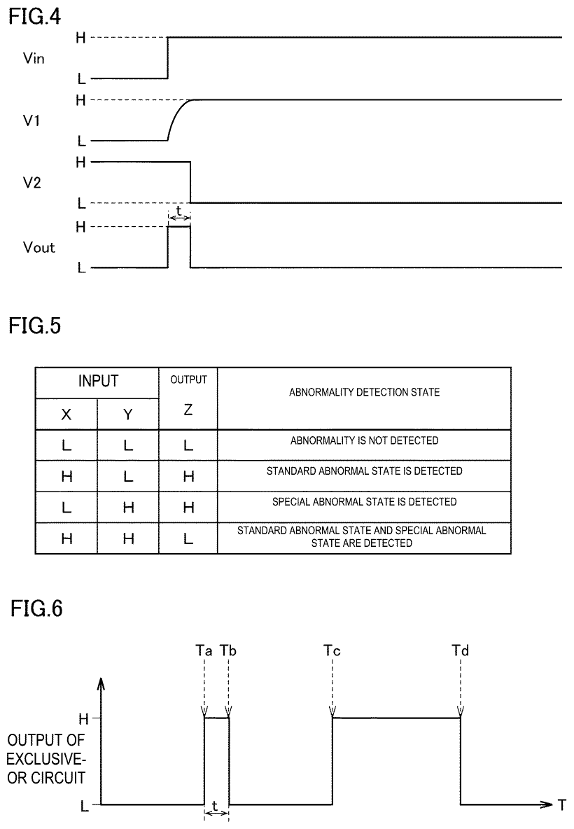

FIG. 4 is a timing chart showing signal levels at respective parts of the pulse generation circuit 53. FIG. 4 shows the relationship among the voltage Vin, the voltage V1, the voltage V2, and the voltage Vout.

Referring to FIG. 4, for example, when the first selection switch 51 is turned on and the detection signal of the first detection circuit 11 changes from low to high, the voltage Vin changes from low to high. When the voltage Vin changes to high, the voltage V1 changes from low to high after a delay period t determined by a time constant of the RC circuit.

When the voltage V1 changes to high, the voltage V2, the level of which is inverted by the inverting circuit 533, changes from high to low. The voltage Vin is input to the first input terminal of the AND circuit 534, and the voltage V2 is input to the second input terminal of the AND circuit 534. The output voltage Vout of the AND circuit 534 is low before the voltage Vin changes to high because the voltage Vin and the voltage V1 are low, is high in a period t corresponding to the delay period t from when the voltage Vin changes to high until when the voltage V2 changes to low after the delay, and then changes to low.

With this configuration, a voltage out output from the AND circuit 534, that is, the voltage Vout of the output terminal 535, becomes a single-shot pulse signal that becomes high for the period t when the voltage V1 changes from low to high. Accordingly, when the input signal becomes high, the pulse generation circuit 53 outputs a single-shot pulse signal.

Here, the pulse generation circuit 53 may also be implemented by a pulse generation circuit other than that illustrated in FIG. 3 as long as the pulse generation circuit can output a single-shot pulse signal.

### (Relationship Between Inputs and Outputs of Exclusive-OR Circuit 42)

Next, the relationship between inputs and outputs of the exclusive-OR circuit 42 is described.

FIG. 5 is a truth table showing the relationship between the inputs and outputs of the exclusive-OR circuit 42. FIG. 5 shows the relationship between a combination of an input signal X from the OR circuit 41 to the exclusive-OR circuit 42 and an input signal Y from the pulse generation circuit 53 to the exclusive-OR circuit 42 and an output signal Z from the exclusive-OR circuit 42. FIG. 5 also show the relationship between the states of the input signals X and Y and the output signal Z and abnormality detection states.

When the input signals X and Y are low, the output signal Z becomes low. This relationship indicates that no abnormality is detected. When the input signal X is high and the input signal Y is low, the output signal Z becomes high. This relationship indicates that a standard abnormal state is detected.

When the input signal X is low and the input signal Y is high, the output signal Z becomes high. This relationship indicates that a special abnormal state is detected. When the input signals X and Y are high, the output signal Z becomes low. This relationship indicates that a standard abnormal state and a special abnormal state are detected simultaneously.

### (Examples of Abnormal State Determination Based on Output Signals of Exclusive-OR Circuit 42)

Next, examples of abnormal state determination based on output signals of the exclusive-OR circuit 42 are described. FIG. 6 is a timing chart showing a first example of abnormal state determination based on an output signal of the exclusive-OR circuit 42. FIG. 6 shows an example in which the standard abnormal state occurs after the special abnormal state is detected.

Referring to FIG. 6, when the special abnormal state is detected at a timing Ta, a single-shot pulse signal is input at the timing Ta to the exclusive-OR circuit 42 from the pulse generation circuit 53 of the bypass circuit 50. As a result, the output signal of the exclusive-OR circuit 42 becomes high for a period t between the timing Ta and a timing Tb. Then, when the standard abnormal state is detected during a period between a timing Tc and a timing Td, a high-level signal is input to the exclusive-OR circuit 42 from the OR circuit 41 during the period between the timing Tc and the timing Td. As a result, the output signal of the exclusive-OR circuit 42 becomes high for the period between the timing Tc and the timing Td.

In the first example shown in FIG. 6, it is possible to determine that the special abnormal state has been detected when the output signal of the exclusive-OR circuit 42 becomes high with a single-shot pulse in the period between the timing Ta and the timing Tb. In the first example shown in FIG. 6, it is possible to determine that the standard abnormal state has been detected when the output signal of the exclusive-OR circuit 42 remains high for the period between the timing Tc and the timing Td that is longer than the period t for which the single-shot pulse is high.

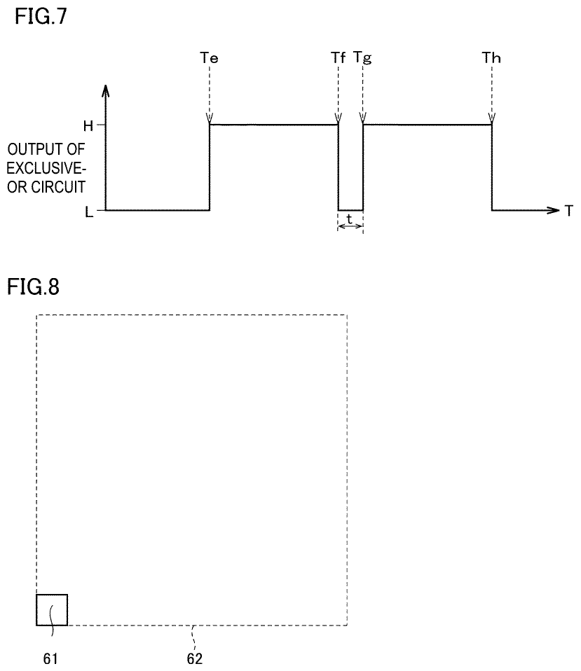

FIG. 7 is a timing chart showing a second example of abnormal state determination based on an output signal of the exclusive-OR circuit 42. FIG. 7 shows an example in which the special abnormal state is detected while the standard abnormal state is detected.

Referring to FIG. 7, when the standard abnormal state is detected at a timing Te, a high-level signal is input from the OR circuit 41 for a period between the timing Te and a timing Th. As a result, the output signal of the exclusive-OR circuit 42 becomes basically high for the period between the timing Te and the timing Th. When the special abnormal state is detected at a timing Tf in the period between the timing Te and the timing Th, a single-shot pulse signal is input from the pulse generation circuit 53 of the bypass circuit 50 to the exclusive-OR circuit 42 at the timing Tf. As a result, according to the relationship shown in FIG. 5, the output signal of the exclusive-OR circuit 42 changes from high to low for a period t between the timing Tf and a timing Tg.

In the second example shown in FIG. 7, it is possible to determine that the standard abnormal state has been detected when the output signal of the exclusive-OR circuit 42 remains high for the period between the timing Te and the timing Th that is longer than the period t for which the single-shot pulse is high. When the output signal of the exclusive-OR circuit 42 changes from high to low during the period t between the timing Tf and the timing Tg, it is possible to determine that the special abnormal state has been detected during the period between the timing Tf and the timing Tg.

The abnormality detection device 10a of the second embodiment can achieve effects as described below in addition to the effects achieved by the abnormality detection device 10 of the first embodiment. With the abnormality detection device 10a, as described above using FIGS. 6 and 7, it is possible to indicate whether the special abnormal state has been detected and also indicate that the standard abnormal state has been detected based on changes in a signal output from the exclusive-OR circuit 42. Accordingly, with the abnormality detection device 10a, it is possible to indicate whether the special abnormal state has been detected and to indicate that the standard abnormal state has been detected based on changes in the signal output from the output terminal 6.

### Third Exemplary Embodiment

(Another Example of Setting of Abnormality Selection Circuit 3 when Outputting Signal Corresponding to Detection of Special Abnormal State)

A third exemplary embodiment describes another example of a setting of the abnormality selection circuit 3 when the bypass circuit 5 or 50 is set to output a signal indicating the detection of the special abnormal state using the first selection switch 51 and the second selection switch 52.

In the example described in the first exemplary embodiment and the second exemplary embodiment, even when the first selection switch 51 or the second selection switch 52 is turned on, the first selection circuit 31 and the second selection circuit 32 corresponding to the first detection circuit 11 and the second detection circuit 12, which correspond to the first selection switch 51 and the second selection switch 52, are set by the mask register 33 to output signals according to signals input from the first register 21 and the second register 22.

However, it is noted that the present disclosure is not limited to this example. As another example, when one of the first selection switch 51 and the second selection switch 52 is turned on, the first selection circuit 31 or the second selection circuit 32, which corresponds to the first detection circuit 11 or the second detection circuit 12 corresponding to the other one of the first selection switch 51 and the second selection switch 52, may be set by the mask register 33 to not output a signal according to a signal input from the corresponding one of the first register 21 and the second register 22.

With the above setting, no signal indicating the detection of an abnormal state is output when the abnormal state need not be addressed quickly after being detected. This configuration enables an abnormal state to be selected that needs to be addressed from abnormal states that are indicated by signals output from the OR circuit 41 via the output terminal 6. This configuration in turn enables an abnormal state to be addressed quickly.

### [Examples of Circuit Area and Pad Area for Output Terminal in First Through Third Embodiments]

Next, examples of a circuit area and a pad area for an output terminal in the first through third embodiments are described with reference to a visual image illustrated in FIG. 8.

With the semiconductor device 100 illustrated in each of FIGS. 1 and 2, to output an abnormality detection signal output from the output terminal 6 to the outside of the semiconductor device 100, it is necessary to provide a pad, which is an electrode made of a metal film for signal output, on a semiconductor substrate on which the semiconductor device 100 is formed. One pad needs to be provided for each output terminal. Accordingly, it is necessary to provide a number of pads that is the same as the number of output terminals.

FIG. 8 illustrates an example of the area of a circuit and the area of a pad for signal output in each of the first through third embodiments. Referring to FIG. 8, on the semiconductor substrate on which the semiconductor device 100 illustrated in each of FIGS. 1 and 2 is formed, the chip area of a circuit region 61, in which circuits forming the abnormality detection device 10 or 10a are formed, is, for example, 36 μm². This example is based on an assumption that circuits forming the abnormality detection device 10/10a are implemented by approximately 600 transistors, and the chip area for each transistor is 0.06 μm².

Referring to FIG. 8, on the semiconductor substrate on which the semiconductor device 100 illustrated in each of FIGS. 1 and 2 is formed, each pad region 62, in which a pad for signal output is provided, requires a chip area of, for example, 60 μm×60 μm=360 μm². In FIG. 8, the chip area of the circuit region 61 is contrasted with the chip area of the pad region 62.

As illustrated in FIG. 8, the pad region 62 requires a large chip area that is about 100 times greater than the chip area of the circuit region 61. Therefore, when output terminals are provided for respective abnormality detection signals as in the related art, the pad region for, for example, five output terminals requires a chip area that is five times greater than the chip area for one pad region 62 illustrated in FIG. 8. Thus, through the comparison between the circuit region 61 and the pad region 62 in FIG. 8, it is apparent that the related-art configuration excessively increases the area of the semiconductor substrate. In contrast, each of the abnormality detection devices 10 and 10a of the first through third embodiments includes only one output terminal 6 for outputting abnormality detection signals. This configuration reduces the area of a semiconductor substrate used to output abnormality detection signals.

### Variations of the Exemplary Embodiments

Next, other variations of the exemplary embodiments of the present disclosure are described.

In the first through third embodiments, one type of voltage is used as an example of a monitor voltage. However, various types of voltages, such as a power supply voltage of the semiconductor device 100, an internal regulator voltage, an output voltage, a temperature sensor voltage, and a difference voltage of a redundant temperature sensor, may be used as monitor voltages according to various exemplary aspects.

In the first through third embodiments, as an example, two detection circuits including the first detection circuit 11 and the second detection circuit 12 are used to detect abnormalities corresponding to one type of monitor voltage. However, the abnormality detection circuit 1 may include three or more detection circuits for one type of monitor voltage. In this case, each of the number of registers in the abnormality storage register 2, the number of selection circuits in the abnormality selection circuit 3, and the number of selection switches in the bypass circuit 5/50 corresponds to the number of detection circuits.

In the first through third embodiments, two detection circuits are provided for one type of monitor voltage in the exemplary aspect. However, the present disclosure is not limited to this configuration. When one type of abnormal state is to be detected based on one type of monitor voltage, one detection circuit may be provided for one type of monitor voltage. In this case, each of the number of registers in the abnormality storage register 2, the number of selection circuits in the abnormality selection circuit, and the number of selection switches in the bypass circuit 5/50 corresponds to the number of detection circuits.

In the bypass circuit 5 of the first embodiment, one signal path is provided for multiple selection switches including the first selection switch 51 and the second selection switch 52 in the exemplary aspects. However, the present disclosure is not limited to this configuration. Instead, multiple signal paths may be provided for multiple selection switches so that signals from the multiple selection switches are input to the OR circuit 41 via the multiple signal paths.

Features of the exemplary embodiments of the present disclosure are summarized below.

<1> An abnormality detection device (abnormality detection device 10) is provided that is configured to detect multiple abnormal states that are likely to occur in a semiconductor device (e.g., semiconductor device 100). The abnormality detection device includes multiple detection circuits (e.g., first detection circuit 11 and second detection circuit 12) that are provided for the corresponding abnormal states and output first signals when detecting the corresponding abnormal states; multiple registers (e.g., first register 21 and second register 22) that are provided for the corresponding detection circuits (e.g., first detection circuit 11 and second detection circuit 12), store data corresponding to the first signals input from the corresponding detection circuits, and output second signals based on the stored data; multiple selection circuits (e.g., first selection circuit 31 and second selection circuit 32) that are provided for the corresponding registers (e.g., first register 21 and second register 22) and determine whether to output third signals based on the second signals input from the corresponding registers; an OR circuit (e.g., OR circuit 41) that is configured to receive the third signals from the selection circuits and output a fourth signal based on the received third signals; and one output terminal (e.g., output terminal 6) that outputs the fourth signal output from the OR circuit as an abnormality detection signal indicating the detection of an abnormal state (see FIG. 1).

<2> According to an exemplary aspect, the abnormality detection device (abnormality detection device 10) described in <1> can further include a bypass circuit (e.g., bypass circuit 5) that includes multiple selection switches (e.g., first selection switch 51 and second selection switch 52), which are provided for the corresponding detection circuits (e.g., first detection circuit 11 and second detection circuit 12) and configured to select the corresponding detection circuits, and inputs the first signals output from the detection circuits selected by the selection switches (e.g., first selection switch 51 and second selection switch 52) to the OR circuit (e.g., OR circuit 41) by bypassing the corresponding registers and selection circuits. The OR circuit (e.g., OR circuit 41) outputs the fourth signal based on one of the first signals input from the bypass circuit (e.g., bypass circuit 5) and the third signals receivable from the selection circuits (see FIG. 1).

<3> Furthermore, an abnormality detection device (abnormality detection device 10a) in an exemplary aspect is configured to detect multiple abnormal states that are likely to occur in a semiconductor device (e.g., semiconductor device 100). The abnormality detection device (e.g., abnormality detection device 10a) includes multiple detection circuits (e.g., first detection circuit 11 and second detection circuit 12) that are provided for the corresponding abnormal states and output first signals when detecting the corresponding abnormal states; multiple registers (e.g., first register 21 and second register 22) that are provided for the corresponding detection circuits (e.g., first detection circuit 11 and second detection circuit 12), store data corresponding to the first signals input from the corresponding detection circuits, and output second signals based on the stored data; multiple selection circuits (e.g., first selection circuit 31 and second selection circuit 32) that are provided for the corresponding registers (e.g., first register 21 and second register 22) and determine whether to output third signals based on the second signals input from the corresponding registers; an OR circuit (e.g., OR circuit 41) that is configured to receive the third signals from the selection circuits and outputs a fourth signal based on the received third signals; a bypass circuit (e.g., bypass circuit 50) that outputs a fifth signal corresponding to one of the first signals output from a detection circuit selected from the detection circuits, by bypassing the corresponding one of the registers and the corresponding one of the selection circuits; an exclusive-OR circuit (e.g., exclusive-OR circuit 42) that is configured to receive the fourth signal output from the OR circuit (e.g., OR circuit 41) and the fifth signal output from the bypass circuit (e.g., bypass circuit 50) and outputs a sixth signal based on the received fourth and fifth signals; and one output terminal (e.g., output terminal 6) that outputs the sixth signal output from the exclusive-OR circuit (e.g., exclusive-OR circuit 42) as an abnormality detection signal indicating the detection an abnormal state. The bypass circuit (e.g., bypass circuit 50) includes multiple selection switches (e.g., first selection switch 51 and second selection switch 52) that are provided for the corresponding detection circuits (e.g., first detection circuit 11 and second detection circuit 12) and configured to select the corresponding detection circuits; and a pulse generation circuit (e.g., pulse generation circuit 53) that outputs the fifth signal implemented by a single-shot pulse signal based on the one of the first signals output from the detection circuit selected by one of the selection switches (e.g., first selection switch 51 and second selection switch 52) (see FIGS. 2 to 4).

<4> In another exemplary aspect, the abnormality detection device (e.g., abnormality detection device 10a) described in <3>, the sixth signal is able to indicate whether the abnormal state has been detected by the detection circuit selected by the one of the selection switches (e.g., first selection switch 51 and second selection switch 52) based on changes in a signal level (see FIGS. 6 and 7).

<5> In yet another exemplary aspect, for the abnormality detection device described in any one of <2> to <4>, one of the selection circuits corresponding to a detection circuit not selected by the selection switches (e.g., first selection switch 51 and second selection switch 52) is configured to not output a third signal corresponding to a second signal from the corresponding one of the registers (see the third embodiment).

It is noted that the above-disclosed embodiments should be considered as examples and not restrictive in all respects.

### REFERENCE SIGNS LIST

100 semiconductor device; 10, 10a abnormality detection device; 11 first detection circuit; 12 second detection circuit; 21 first register; 22 second register; 31 first selection circuit; 32 second selection circuit; 41 OR circuit; 6 output terminal; 51 first selection switch; 52 second selection switch; 5, 50 bypass circuit; 42 exclusive-OR circuit

What is claimed:

1. An abnormality detection device for detecting abnormal states of a semiconductor device, the abnormality detection device comprising:
a plurality of detection circuits that are configured to output first signals when detecting the abnormal states, respectively;
a plurality of registers that correspond to the plurality of detection circuits, the plurality of registers being configured to store data corresponding to the first signals input from the respective detection circuits, and to output second signals based on the stored data;
a plurality of selection circuits that correspond to the plurality of registers and are configured to determine whether to output third signals based on the second signals from the plurality of registers, respectively;
an OR circuit configured to receive the third signals from the plurality of selection circuits and to output a fourth signal based on the received third signals; and
an output terminal configured to output the fourth signal from the OR circuit as an abnormality detection signal that indicates a detection of an abnormal state.

2. The abnormality detection device according to claim 1, further comprising a bypass circuit that includes a plurality of selection switches for the plurality of detection circuits, respectively, and that are configured to select the corresponding detection circuit and input the first signals output from the detection circuits selected by the selection switches to the OR circuit by bypassing the corresponding registers and selection circuits.

3. The abnormality detection device according to claim 2, wherein the OR circuit is configured to output the fourth signal based on one of the first signals input from the bypass circuit and the third signals from the respective selection circuit.

4. The abnormality detection device according to claim 1, further comprising a voltage monitor circuit that is configured to convert a current value detected in the semiconductor device into a voltage value that is output as a monitor voltage.

5. The abnormality detection device according to claim 4, further comprising:
a first threshold storage circuit configured to store an upper limit voltage as a first threshold value; and
a second threshold storage circuit configured to store a lower limit voltage as a second threshold value.

6. The abnormality detection device according to claim 5, wherein the plurality of detection circuits includes a first detection circuit that is a comparator configured to compare the monitor voltage to the first threshold value and to output the respective first signal as a high value indicating an abnormal state when the monitor voltage is greater than the first threshold value.

7. The abnormality detection device according to claim 6, wherein the plurality of detection circuits includes a second detection circuit that is a comparator configured to compare the monitor voltage to the second threshold value and to output the respective first signal as a high value indicating an abnormal state when the monitor voltage is less than the second threshold value.

8. The abnormality detection device according to claim 1, wherein the plurality of selection circuits are each AND circuits having a first input configured to receive a respective second signal from one of the plurality of registers and a second input coupled to a mask register.

9. The abnormality detection device according to claim 8, wherein the mask register is configured to select at least one of the plurality of selection circuits to output a signal corresponding to the second signal output from the respective register.

10. The abnormality detection device according to claim 9, wherein the mask register is configured to be adjusted by a user.

11. An abnormality detection device for detecting abnormal states in a semiconductor device, the abnormality detection device comprising:
a plurality of detection circuits that are configured to output first signals when detecting the abnormal states, respectively;
a plurality of registers that correspond to the plurality of detection circuits, the plurality of registers being configured to store data corresponding to the first signals from the respective detection circuits, and to output second signals based on the stored data;
a plurality of selection circuits that correspond to the plurality of registers and are configured to determine whether to output third signals based on the second signals from the plurality of registers, respectively;
an OR circuit configured to receive the third signals from the plurality of selection circuits and to output a fourth signal based on the third signals;
a bypass circuit configured to output a fifth signal that corresponds to one of the first signals output from a detection circuit selected from the plurality of detection circuits, by bypassing a corresponding one of the plurality of registers and a corresponding one of the plurality of selection circuits;
an exclusive-OR circuit configured to receive the fourth signal output from the OR circuit and the fifth signal from the bypass circuit and to output a sixth signal based on the received fourth and fifth signals; and
an output terminal configured to output the sixth signal from the exclusive-OR circuit as an abnormality detection signal indicating detection of an abnormal state.

12. The abnormality detection device according to claim 11, wherein the bypass circuit includes a plurality of selection switches that correspond to the plurality of detection circuits, respectively, and are configured to select the corresponding detection circuit.

13. The abnormality detection device according to claim 12, further comprising a pulse generation circuit configured to output the fifth signal implemented by a single-shot pulse signal based on the one of the first signals output from the detection circuit that is selected by one of the plurality of selection switches.

14. The abnormality detection device according to claim 13, wherein the bypass circuit includes the pulse generation circuit.

15. The abnormality detection device according to claim 13, wherein the sixth signal indicates whether the abnormal state has been detected by the detection circuit selected by the one of the plurality of selection switches based on at least one change in a signal level.

16. The abnormality detection device according to claim 13, wherein the one of the plurality of selection circuits that corresponds to one of the plurality of detection circuits, which is not selected by the plurality of selection switches, is configured to not output a third signal corresponding to a second signal from a corresponding one of the plurality of registers.

17. The abnormality detection device according to claim 11, further comprising a voltage monitor circuit that is configured to convert a current value detected in the semiconductor device into a voltage value that is output as a monitor voltage.

18. The abnormality detection device according to claim 17, further comprising:
a first threshold storage circuit configured to store an upper limit voltage as a first threshold value; and
a second threshold storage circuit configured to store a lower limit voltage as a second threshold value.

19. The abnormality detection device according to claim 18, wherein the plurality of detection circuits includes a first detection circuit that is a comparator configured to compare the monitor voltage to the first threshold value and to output the respective first signal as a high value indicating an abnormal state when the monitor voltage is greater than the first threshold value.

20. The abnormality detection device according to claim 19, wherein the plurality of detection circuits includes a second detection circuit that is a comparator configured to compare the monitor voltage to the second threshold value and to output the respective first signal as a high value indicating an abnormal state when the monitor voltage is less than the second threshold value.
